(19) United States
(12) Patent Application Publication
(10) Pub. No.: US 2025/0386633 A1
(43) Pub. Date: Dec. 18, 2025

(54) ELECTRONICALLY FUNCTIONAL MULTILAYER STRUCTURE

(71) Applicant: Continental Automotive Technologies GmbH, Hannover (DE)

(72) Inventors: Paul Werner, Brunn im Felde (AT); Alexander Raab, Wien (AT); Andreas Egger, Groß-Enzersdorf (AT); Ulrich Gartner, Wien (AT)

(73) Assignee: Continental Automotive Technologies GmbH, Hannover (DE)

(21) Appl. No.: 19/241,889

(22) Filed: Jun. 18, 2025

(30) Foreign Application Priority Data
Jun. 18, 2024 (DE) 10 2024 205 624.3

(51) Int. Cl. H10H 29/24; G06F 3/041; H10H 29/852

(52) U.S. Cl. CPC H10H 29/24; H10H 29/852; G06F 3/041

(57) ABSTRACT

An electronically functional multilayer structure having a first film on which first electrical and/or electronic components are arranged on a first film surface and having a second film on which second electrical and/or electronic components are arranged on a first film surface. The two films are arranged on top of each other in such a way that their sides having the respective first film surfaces face each other, there being a gap between the two films in the region of the first and second electrical and/or electronic components.

### CROSS-REFERENCE TO RELATED APPLICATIONS

This application claims priority to German patent application No. 10 2024 205 624.3, filed Jun. 18, 2024, which is hereby incorporated by reference.

### TECHNICAL FIELD

The technical field relates to an electronically functional multilayer structure on which electrical and/or electronic components are arranged.

### BACKGROUND

Such an electronically functional multilayer structure is known from U.S. Pat. No. 11,416,081 B1. This comprises a flexible, 3D-malleable substrate film having a first surface facing the inner parts of the structure and an opposing second surface facing an environment of the structure and a user therein, the first and second surface and the remaining material of the substrate film lying therebetween locally defining a three-dimensional projection which extends from a plane of the surrounding substrate film material and is formed of locally stretched and formed material of the substrate film and forms side walls through which touch is able to be detected. The circuit provided on the substrate film comprises a number of conductive conductor tracks, electrodes and/or components for detecting touches on two or more of the plurality of side walls and at least one filling layer on the substrate film in order to at least partially embed the circuit.

Arranged between the two films is thus an injection-molding layer which at least partially surrounds the first electrical and/or electronic components on the first film. As a result, they are exposed to increased stress during the injection-molding process.

Such electronically functional multilayer structures can be advantageously used for operating elements in vehicles. The installation space for structures having illuminated operating elements in the automotive sector (especially in the roof area) is becoming increasingly smaller. Customary concepts using conventional PCBs and LEDs, including required light shafts for the light emitted by the LEDs, are becoming increasingly more difficult to integrate into currently provided installation spaces in a vehicle since they require too much installation space.

However, there is a higher risk of failure rates because the LEDs and conductor tracks are directly exposed to the injection pressure. If individual LEDs fail, the entire component has to be disposed of.

As such, it is desirable to present a less sensitive multilayer structure. In addition, other desirable features and characteristics will become apparent from the subsequent summary and detailed description, and the appended claims, taken in conjunction with the accompanying drawings and this background.

### SUMMARY

In one embodiment, an electronically functional multilayer structure includes a first film on which first electrical and/or electronic components are arranged on a first film surface, a second film on which second electrical and/or electronic components are arranged on a first film surface, the two films being arranged on top of each other in such a way that their sides having the respective first film surfaces face each other, there being an air gap between the two films in the region of the first and second electrical and/or electronic components.

In this case, a second film surface of the first film can be provided with a first injection-molding layer which is laminated, adhesively bonded or produced by similar joining or connecting processes.

The multilayer structure is thus produced by an overmolded, laminated, adhesively bonded or foamed film structure having a haptic surface and integrated LEDs as well as touch functions. The LEDs are adhesively bonded to a film and the conductor tracks are printed on. This LED film or flexible PCB can optionally be overmolded, laminated, adhesively bonded or foamed from below, the LEDs and conductor tracks advantageously not being exposed to any injection pressure. The touch surfaces are printed on a further film or one of the existing films (depending on the choice of material and film thickness), which can be a cover film or decorative film, that is to say can have printed symbols, the decor pointing toward an environment in which a user can operate the haptic surface. The printed symbols can be printed on the top side or bottom side, depending on preference: visible without power or not—or function: safety-relevant or not.

The first electrical and/or electronic components can thus be formed at least by conductor tracks and optically radiating components, while the second electrical and/or electronic components can be formed at least by conductor tracks and touch or contact-sensitive components.

In one development of the multilayer structure, arranged on the second film surface of the second film is a third film the surface of which facing away from the second film is provided with printed symbols.

In this case, arranged between the second and the third film is a second injection-molding layer (laminated, adhesively bonded or similar joining or connecting processes).

The region between the second touch film and the third optional decorative film can be filled utilizing 2K injection molding (multi-component laminated, adhesively bonded or similar joining or connecting processes). Here too, the conductor tracks are not exposed to any injection pressure because they are attached to the outside of the component. The two injection-molding elements, which are formed by the first film having an optional first injection-molding layer or the second film having an optional second injection-molding layer and an optional third (decorative) film, are then connected to each other at their edge region or at any other possible position in a form- and/or force-fitting manner, the result of which is a single, very flat component.

Advantageously, in one embodiment of the multilayer structure, the second film and—if present—the second injection-molding layer has or have, in the region of LEDs arranged on the first film, openings for the light of the LEDs, which openings are filled with optically transparent material. This allows the light of the LEDs on the first film to pass through the decorative film. The use of simple and high-quality optics is possible by means of lenses, spreading disks, etc.

Arranged on the first injection-molding layer and/or on the second injection-molding layer can be domes or bars projecting into the air gap between the two films in order to ensure sufficient mechanical strength and dimensional stability. These bars or domes can also be used to prevent stray light between the various LEDs.

The first injection-molding layer and the second injection-molding layer can have a connection at their edge regions, in particular in the form of rivets, which are formed by one of the injection-molding layers.

Owing to the measures described herein, the entire multilayer structure can have a maximum thickness of a few millimeters.

Printed conductor tracks and adhesively bonded LEDs on a film, as well as printed touch surfaces on a further film and the embedding of the films by rear-side overmolding, laminating, adhesively bonding or foaming thus enable a very flat design of A-surfaces and the integration of all lighting and touch functions into a single component.

The rear-side injection-molding process (or laminated, adhesively bonded or similar joining or connecting processes) ensures that the conductor tracks and LEDs are not subjected to the injection pressure, this greatly reducing the risk and the resulting cost of failure rates.

The failure rates can also be reduced because in the event of defective LEDs, the entire overmolded, laminated, adhesively bonded or foamed component does not have to be disposed of if the test can be carried out before the two component halves are combined and the further production steps do not have any significant influence on OK and not OK status. An A-surface and an LED functional component can be produced and tested separately, as a result of which the failure rates in the event of defective components can be reduced.

### BRIEF DESCRIPTION OF THE DRAWINGS

The disclosed subject matter is described in more detail below on the basis of an exemplary embodiment with the aid of a FIGURE. In the drawing

FIG. 1 shows a cross section through a multilayer structure having LEDs and touch-sensitive elements.

### DETAILED DESCRIPTION

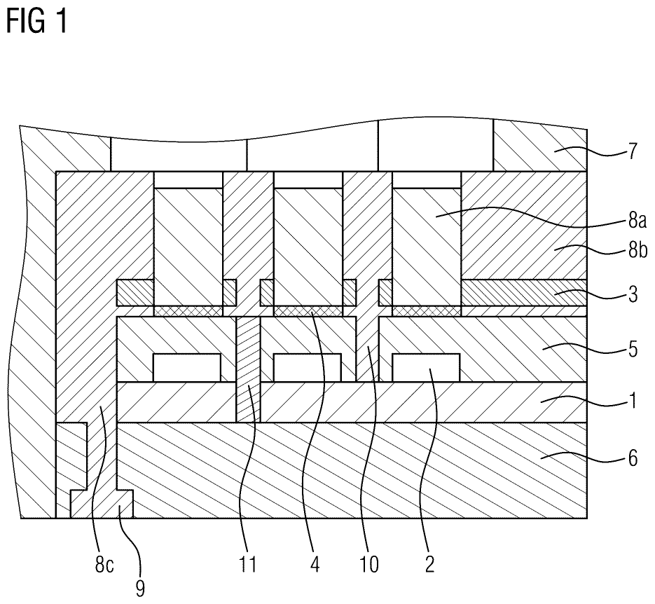

FIG. 1 shows a first film 1 on which electrical and/or electronic components 2 in the form of conductor tracks and at least LEDs are printed or adhesively bonded as electronic components. This first film 1 is provided with a first injection-molding layer 6 on its surface facing away from the surface provided with the electrical and/or electronic components 2. By virtue of this first injection-molding layer 6 being applied to this second film surface, the electrical and/or electronic components 2 are not exposed to the injection-molding pressure. Nevertheless, the film 1 has sufficient stability.

Also shown is a second film 3 to which at least conductor tracks and touch-sensitive regions are attached as electrical and/or electronic components 4, in particular in the region under a second sublayer 8b. This second film 3 can already be provided with printed symbols and haptically identifiable printing regions on its surface facing away from the electrical and/or electronic components 4 and thus act as a decorative film.

In the exemplary embodiment, however, provision is made for a third film 7 which assumes this decorative function. It can be connected directly to the second film 3 but in the exemplary embodiment of FIG. 1 is connected to the second film 3 via a second injection-molding layer 8a, 8b.

In this case, the second injection-molding layer 8a, 8b is formed by a first sublayer 8a which forms optically transparent regions for the light of the LEDs on the first film 1. This first sublayer 8a is surrounded by a second sublayer 8b which supports the entire second injection-molding layer.

The LEDs can also be placed in an air gap between the second film 3 and the first sublayer 8a if the second sublayer 8b has considerably thinner wall thicknesses than the first sublayer 8a. This also results in a flatter construction.

The first injection-molding layer 6 has domes or bars 11 which project through the first film 1 and into the air gap 5. In the same way, the second injection-molding layer 8a, 8b has domes or bars 10 which project through the second film 3 and into the air gap 5. These domes or bars 10, 11 support the entire multilayer structure and give it dimensional stability. Moreover, these domes or bars 10, 11 can prevent stray light between the LEDs.

The two substructures from the first film 1 and the first injection-molding layer 6 or the second film 3, the second injection-molding layer 8a, 8b and the third film 7 can be manufactured and also tested separately.

They are then joined together with their surfaces provided with the electrical and/or electronic components 2, 4 facing each other to form the multilayer structure. For this purpose, as can be seen in FIG. 1, use can be made of a hot rivet connection 9 which is connected to the laterally extended second injection-molding sublayer 8c through an edge region of the first injection-molding layer 6. The third film 7 can also be applied across the sides of the multilayer structure in order to form an optically appealing surface facing a user.

1. An electronically functional multilayer structure, comprising:
a first film on which first electrical and/or electronic components are arranged on a first film surface;
a second film on which second electrical and/or electronic components are arranged on a first film surface;
wherein the two films are arranged on top of each other in such a way that their sides having the respective first film surfaces face each other; and
a gap between the two films in the region of the first and second electrical and/or electronic components.

2. The electronically functional multilayer structure as claimed in claim 1, wherein the gap is filled with a gas.

3. The electronically functional multilayer structure as claimed in claim 1, wherein there is a vacuum in the gap.

4. The electronically functional multilayer structure as claimed in claim 1, wherein the first electrical and/or electronic components are formed at least by conductor tracks and optically radiating components.

5. The electronically functional multilayer structure as claimed in claim 1, wherein the second electrical and/or electronic components are formed at least by conductor tracks and touch or contact-sensitive components.

6. The electronically functional multilayer structure as claimed in claim 1, wherein the second film surface of the first film is provided with a first injection-molding layer.

7. The electronically functional multilayer structure as claimed in claim 6, wherein the second film surface of the second film is provided with printed symbols.

8. The electronically functional multilayer structure as claimed in claim 7, wherein arranged on the second film surface of the second film is a third film the surface of which facing away from the second film is provided with printed symbols.

9. The electronically functional multilayer structure as claimed in claim 8, wherein arranged between the second film and the third film is a second injection-molding layer.

10. The electronically functional multilayer structure as claimed in claim 9, further comprising LEDs disposed on the first film and wherein the second film and the second injection-molding layer include openings for the light of the LEDs, the openings being filled with material that is permeable to light.

11. The electronically functional multilayer structure as claimed in claim 10, wherein arranged on the first injection-molding layer are domes projecting into the gap.

12. The electronically functional multilayer structure as claimed in claim 11, wherein arranged on the second injection-molding layer are domes projecting into the gap.

13. The electronically functional multilayer structure as claimed in claim 9, wherein the first injection-molding layer and the second injection-molding layer have a connection at their edge regions.
